(19) United States
(12) Patent Application Publication
(10) Pub. No.: US 2006/0118955 A1
(43) Pub. Date: Jun. 8, 2006

(54) Robust copper interconnection structure and fabrication method thereof

(75) Inventor: Chung-Shi Liu, Hsinchu City (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD., Hsin-Chu (TW)

(21) Appl. No.: 11/002,256

(22) Filed: Dec. 3, 2004

(51) Int. Cl. H01L 23/52; H01L 21/469

(52) U.S. Cl. 257/753; 257/760; 257/762; 438/652; 438/687; 438/763

(57) ABSTRACT

An interconnect structure has a silicon nitride layer overlying a substrate with a conductive region, a silicon carbide layer overlying the silicon nitride layer, and a dielectric layer having a dielectric constant less than 3.9 overlying the silicon carbide layer. A conductive layer is inlaid the dielectric layer, the silicon carbide layer and the silicon nitride layer to electrically connect to the conductive region.

### FIELD OF THE INVENTION

The present invention relates to interconnection technologies, and particularly to a copper interconnect structure integrated with a low dielectric constant material layer using a composite etch stop structure.

### BACKGROUND OF THE INVENTION

Microelectronic integrated circuits based on patterned semiconductor materials are continuing to evolve towards devices with an extremely high density of circuit elements per unit volume. As the features of these devices are reduced to smaller sizes, the performance of the materials that constitute the device will critically determine their success. One specific area in need of advancement is the smaller conducting interconnects composed of materials with higher conductivity and greater mechanical integrity, which presently favors the use of copper (Cu), with twice the conductivity of aluminum and three times the conductivity of tungsten, as the material of choice. Another specific area in need of advancement is the electrical insulator used between the wires, metal lines, and other elements of the circuit. An insulating material that possesses a dielectric constant as low as possible, such as a dielectric constant (k) below the dielectric constant of about 4.0 of silicon dioxide, has long been used in integrated circuits as the primary insulating material to avoid increased problems of capacitive coupling (cross-talk) and propagation delay.

Copper damascene process is a well-known technique of inlaying metal for interconnects and wiring through the back end, especially well suited for Ultra Large Scale Integrated (ULSI) circuit technology. The copper damascene process includes etching a via and/or a trench, filling the via/trench with copper, and then removing any overfilling material by chemical mechanical polishing (CMP), for example. Currently, silicon nitride (SiN) or silicon carbide (SiC), for example, may be used to form an etch stop layer which defines the bottom of the trench and/or via as it is formed. Although this type of etch stop may be effective in simplifying the etch process during the formation of the trench and/or via, these etch stop materials generally induce device failure.

The SiN etch stop layer has a problem known as resist poisoning which occurs during a patterning step such as via pattern or trench pattern, especially when low-k dielectrics such as OSG or HSQ are used for the inter-metal dielectric (IMD) layer. This resist poisoning effect is a result of the interaction between a DUV (deep ultra-violet) photoresist and low-k films where nitrogen containing species absorbed into the low-k materials interfere with photoresist development processes, causing poor resist sidewall profiles, resist scum, via RC failure, and large CD variations. U.S. Pat. No. 6,107,188 incorporated herein by reference, describes a composite dielectric including a SiON etch stop and a SiN passivation in copper damascene interconnect processes. Since SiN has a k value around 7.0 and SiON has a k value around 5.5, the combination of low-k IMD layer with the high-k etch stop layers may result in little or no improvement in the overall stack dielectric constant and capacitive coupling. U.S. Pat. No. 6,593,632 incorporated herein by reference, teaches the use of SiC as an etch stop layer. The poor adhesion between SiC and copper, however, results in dielectric peeling when subsequently subjected to stresses such as those induced by chemical mechanical polishing (CMP). U.S. Pat. No. 6,424,038 incorporated herein by reference, describes a SiC layer laminated thereto a SiN layer and formed from a substrate closer to a copper region, but this laminate still encounters the poor adhesion issue between SiC and copper and the resist poisoning effect between SiN and low-k materials.

An etch stop layer to reduce resist poisoning and prevent dielectric peeling is therefore desired. There remains, however, a need for an etch stop layer to achieve a robust copper damascene structure with a lower effective capacitance.

### SUMMARY OF THE INVENTION

It is an object of the present invention to provide a robust copper interconnect structure using a composite etch stop structure including a silicon nitride layer laminated thereto a silicon carbide layer.

It is another object of the present invention to provide a robust copper interconnect structure to reduce resist poisoning and prevent dielectric peeling.

It is another object of the present invention to provide a robust copper interconnect structure with a lower effective capacitance.

To achieve the above objectives, the present invention provides an interconnect structure comprising: a substrate comprising a conductive region; a silicon nitride layer overlying said substrate; a silicon carbide layer overlying said silicon nitride layer; at least one dielectric layer having a dielectric constant less than 3.9 overlying said silicon carbide layer; and a conductive layer inlaid said at least one dielectric layer, said silicon carbide layer and said silicon nitride layer, wherein said conductive layer is electrically connected to said conductive region.

To achieve the above objectives, the present invention provides an interconnect structure comprising: a substrate comprising a conductive region; a silicon nitride layer overlying said substrate; a silicon carbide layer overlying said silicon nitride layer; a first dielectric layer having a dielectric constant less than 3.9 overlying said silicon carbide layer; a second dielectric layer having a dielectric constant less than 3.9 overlying said first dielectric layer; and a conductive layer within a dual damascene opening formed in said second dielectric layer, said first dielectric layer, said silicon carbide layer and said silicon nitride layer, wherein said conductive layer is electrically connected to said conductive region.

To achieve the above objectives, the present invention provides a fabrication method of forming an interconnect structure, comprising the steps of: providing a substrate having a conductive region; forming a silicon nitride layer overlying said substrate; forming a silicon carbide layer overlying said silicon nitride layer; forming at least one dielectric layer having a dielectric constant less than 3.9 overlying said silicon carbide layer; forming an opening in said at least one dielectric layer, said silicon carbide layer and said silicon nitride layer to expose said conductive region; and filling said opening with a conductive layer.

### BRIEF DESCRIPTION OF THE DRAWINGS

The aforementioned objects, features and advantages of this invention will become apparent by referring to the following detailed description of the preferred embodiment with reference to the accompanying drawings, wherein:

FIGS. 1A to 1D are cross-sectional diagrams illustrating a copper interconnection process according to embodiments of the present invention;

FIGS. 2A to 2B are cross-sectional diagrams illustrating a copper dual damascene process according to an embodiment of the present invention; and

FIG. 3 is a cross-sectional diagram illustrating an exemplary implantation of a copper dual damascene pattern according to the present invention.

### DESCRIPTION OF THE PREFERRED EMBODIMENTS

The present invention provides copper interconnection patterns, particularly employing damascene techniques and low-k dielectric material, which employs a composite SiN/SiC structure as an etch stop layer, alternatively referred to as a polish stop layer, between a copper interconnection and a low-k IMD layer to overcome the aforementioned problems of the prior art. The present invention addresses and solves problems impacting device reliability as feature sizes plunge into the deep sub-micron generation in an effort to satisfy the ever-increasing demands for miniaturization and high circuit speed. In attempting to fabricate a robust Cu damascene integrated with low-k IMD layers, a SiN layer and a SiC layer laminated thereon are used as a composite etch stop structure to reduce or eliminate resist scum, improve dielectric adhesion, prevent dielectric peeling, and lower an effective k value in the overall stack dielectrics as well. As will be appreciated by persons skilled in the art from discussion herein, the present invention has wide applicability to many manufacturers, factories and industries, including but not limited to, integrated circuit fabrications, microelectronic fabrications, and optical electronic fabrications.

As used throughout this disclosure, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium. The term “dielectric” refers to a material in which an electric field can be maintained with zero or near-zero power dissipation, i.e., the electrical conductivity is zero or near zero. The term “low-k” refers to dielectric materials having a dielectric constant (k value) less than about 3.9 for a dielectric material. The term “etch stop” refers to a layer which is deposited on or intermediately in a layer, and is of a different material than a layer overlying the etch stop, and preferably has characteristics which render its etch rate much slower than that of the material overlying it. The result is that the etch stop provides a clear indicator of when to end a particular etching process.

As will be described more fully later, damascene process provides a more exact dimensional control over small geometries, while copper, as the metallization material, provides greater electrical characteristics. The term “damascene” is derived from a manner of inlaid metal. In the context of integrated circuits it implies a patterned layer imbedded on and in another layer such that the top surfaces of the two layers are coplanar. Thus, in semiconductor manufacturing, trenches or/and vias in appropriate locations in the trenches are formed in an insulating material by etching, which are then filled with metal. The damascene process is repeated as many times as required to form the multi-level interconnections between metal lines and the vias formed there between. Although the preferred embodiments of the present invention illustrate copper interconnection patterns using single damascene process and dual damascene process, the present invention provides value when using non-damascene methods.

Hereinafter, reference will now be made in detail to the present preferred embodiments of the invention, examples of which are illustrated in the accompanying drawings. Wherever possible, the same reference numbers are used in the drawings and the description to refer to the same or like parts. In the drawings, the shape and thickness of an embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be presented.

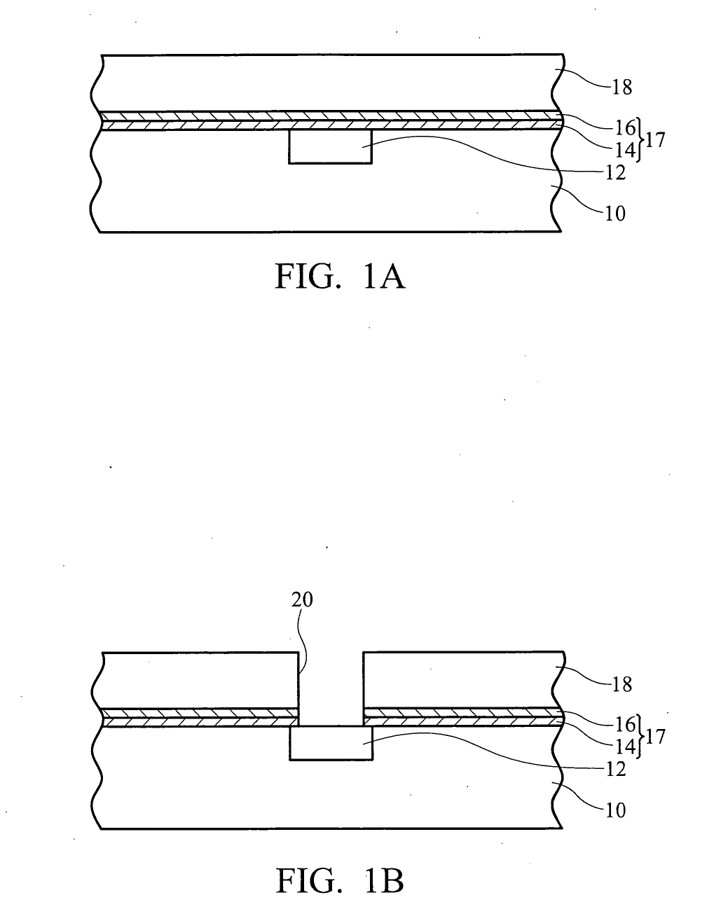

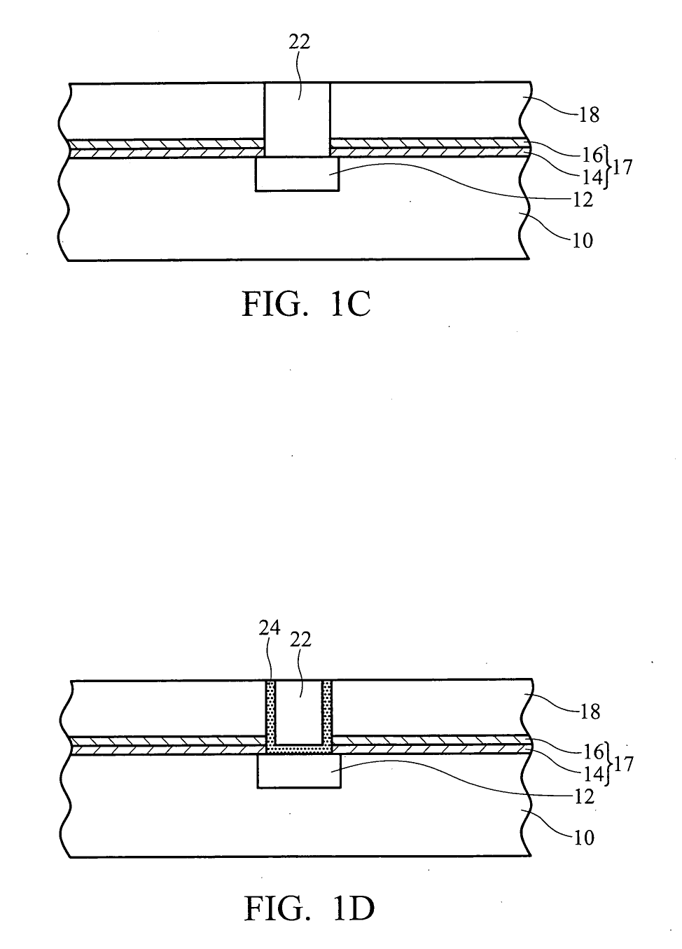

FIGS. 1A to 1D are cross-sectional diagrams illustrating a copper interconnection process according to embodiments of the present invention.

Referring to FIG. 1A, an example of a substrate 10 used for interconnection fabrication is illustrated. The substrate 10 may comprise a semiconductor substrate as employed in a semiconductor integrated circuit fabrication, and integrated circuits may be formed therein and/or thereupon. The term “semiconductor substrate” is defined to mean any construction comprising semiconductor material, including, but not limited to, bulk semiconductor materials such as a semiconductor wafer and semiconductor material layers. The term “integrated circuits” as used herein refers to electronic circuits having multiple individual circuit elements, such as transistors, diodes, resistors, capacitors, inductors, and other active and passive semiconductor devices. The substrate 10 comprises a conductive region 12, which is a portion of conductive routs and has an exposed surface treated by a planarization process, such as chemical mechanical polishing (CMP). Suitable materials for the conductive region 12 may include, but not limited to, for example copper, aluminum, copper alloy, or other mobile conductive materials.

As depicted in FIG. 1A, a silicon nitride layer 14, a silicon carbide layer 16, and a low-k dielectric layer 18 are successively deposited on the substrate 10 to encapsulate the conductive region 12. The silicon nitride layer 14 is SiₓN_{y} (hereinafter merely referred to as “SiN”), wherein x and y are optional integers which are each an optional integer standing for the atom composition ratio. The silicon nitride layer 14 has a thickness of about 10 angstroms to about 1000 angstroms, which may be formed through any of a variety of deposition techniques, including, LPCVD (low-pressure chemical vapor deposition), APCVD (atmospheric-pressure chemical vapor deposition), PECVD (plasma-enhanced chemical vapor deposition), PVD (physical vapor deposition), sputtering, and future-developed deposition procedures. The silicon carbide layer 16 is SiₓC_{y} (hereinafter merely referred to as “SiC”), wherein x and y are optional integers which are each an optional integer standing for the atom composition ratio. The silicon carbide layer 16 has a thickness of about 10 angstroms to about 1000 angstroms, which may be formed through any of a variety of techniques, including, CVD, PECVD, PVD, and future-developed deposition procedures. As appropriate to individual methods, the silicon carbide layer 16 may be in-situ or ex-situ upon the silicon nitride layer 14. One key feature of the present invention is to employ a combination of the SiN layer 14 and the SiC layer 16, hereinafter merely referred to as a composite SiN/SiC structure 17, as an etch stop layer, which has combination functions of prohibiting resist poisoning and dielectric peeling. Another key feature of the present invention is to employ the composite SiN/SiC structure 17 to lower an effective k value in the overall stack dielectrics.

The low-k dielectric layer 18 is preferably formed of a comparatively low dielectric constant dielectric material with a k value less than about 3.9, e.g., 3.5 or less. A wide variety of low-k materials may be employed in accordance with embodiments of the present invention, for example, spin-on inorganic dielectrics, spin-on organic dielectrics, porous dielectric materials, organic polymer or organic silica glass. The organic polymer includes, for example, SiLK (manufactured by The Dow Chemical Co. in the U.S.A., k=2.7) or FLARE of a polyallyl ether (PAE) series material (manufactured by Honeywell Electronic Materials Co., k=2.8). The organic silica glass (SiOC series materials) includes, for example, HSG-R7 (manufactured by Hitachi Kasei Industry Co., k=2.8), Black Diamond (manufactured by Applied Materials Inc. in the U.S.A., k=3.0˜2.4) or p-MTES (manufactured by Hitachi Kaihatsu, k=3.2). Other SiOC series materials may include, for example, CORAL (manufactured by Novellus Systems, Inc., in the U.S.A. k=2.7˜2.4) and Aurora (manufactured by Nippon ASM Co., k=2.7). Further, FSG (SiOF series material), HSQ (hydrogen silsesquioxane, k=2.8˜3.0) series material, MSQ (methyl silsesquioxane, k=2.5˜2.7) series material, porous HSQ series material, porous MSQ material or porous organic series material may also be used. The low-k dielectric layer 18 is formed to a thickness of about 1000 angstroms to about 20000 angstroms through any of a variety of techniques, including, spin coating, CVD, and future-developed deposition procedures.

With reference to FIG. 1B, a via hole 20 is formed in the layers 14, 16 and 18 to expose a portion of the conductive region 12. The via hole 20 may be formed using a typical lithographic and etch operation. For example, a photoresist layer (not shown) is applied to the low-k dielectric layer 18, exposed to impart a latent image pattern characteristic of the via hole 20, and developed to transform the latent image pattern into a final image pattern that defines masked areas and unmasked areas on the low-k dielectric layer 18 at the locations of the via hole 20. Then, portions of the low-k dielectric layer 18 are removed from unmasked areas by a first etch process through any suitable etching process, such as anisotropic etching (e.g. plasma etching or reactive ion etching), that has a very low etch rate for the composite SiN/SiC structure 17 and stops thereupon. For example, the main etch procedure uses an etchant including C₄F₈ of 10˜20 sccm, C₂F₆ of 10˜20 sccm, CO of 30˜50 sccm and Ar. Continuously, portions of the composite SiN/SiC structure 17 are removed from unmasked areas by a second etch process without damage to the low-k dielectric layer 18 and the conductive region 12. For example, the second etch process is an anisotropic etching with an etchant including CF₄, H₂ and N₂ of 50˜200 sccm and a power level of 250˜450 W. The via hole 20 is therefore completed in the layers 18, 16 and 14 to expose the conductive region 12, and the patterned photoresist layer is then stripped.

Referring to FIG. 1C, a conductive layer 22 is formed on the substrate 10 by means of the electroplating method for example, thus completely burying the via hole 20 with the conductive layer 22. The conductive layer 22 extended on to the low-k dielectric layer 18 is then removed by means of CMP or other suitable etch back processes. At this time, it is preferred that the CMP process is performed until the low-k dielectric layer 18 is exposed. With respect to the via-fill conductive material, the conductive layer 22 may include a low resistivity conductor material selected from the group of conductor materials including, but not limited to, copper and copper-based alloy. For example, the via-fill conductive material is formed employing the following process: (1) metal seed layer deposition with 50˜25000 angstroms in thickness; (2) copper layer deposition with 5000˜10000 angstroms in thickness. The metal seed layer may include copper, nickel, molybdenum, platinum, titanium, aluminum, or the like by means of PVD, CVD or atomic layer deposition (ALD) method.

In an embodiment, a barrier layer is further added to provide both an excellent diffusion barrier in combination with good conductivity. As depicted in FIG. 1D, a diffusion barrier layer 24 is conformally deposited along the bottom and sidewalls of the via hole 20 prior to the via-fill conductive material process. The subsequent process for planarizing the conductive layer 22 also removes the diffusion barrier layer 24 extended on to the low-k dielectric layer 18. The diffusion barrier layer 24 may include, but not limited to, a refractory material, TiN, TaN, Ta, Ti, W, WN, Cr, Nb, mixtures thereof, or other materials that can inhibit diffusion of copper into the low-k dielectric layer 18 by means of PVD, CVD or ALD. The diffusion barrier layer 24 may have a thickness of 50˜300 angstroms.

Accordingly, a composite SiN/SiC structure for a copper interconnection process integrated with a low-k IMD layer has been presented that allows reduction or elimination of resist poisoning and resist scum, great improvement in adhesion between copper and the etch stop structure, prevention of dielectric peeling especially during wire bonding package, and reduction in the effective k value in the overall stack dielectrics as well. It is possible to repeat the composite SiN/SiC structure and the copper interconnection process to multi-level interconnection structures.

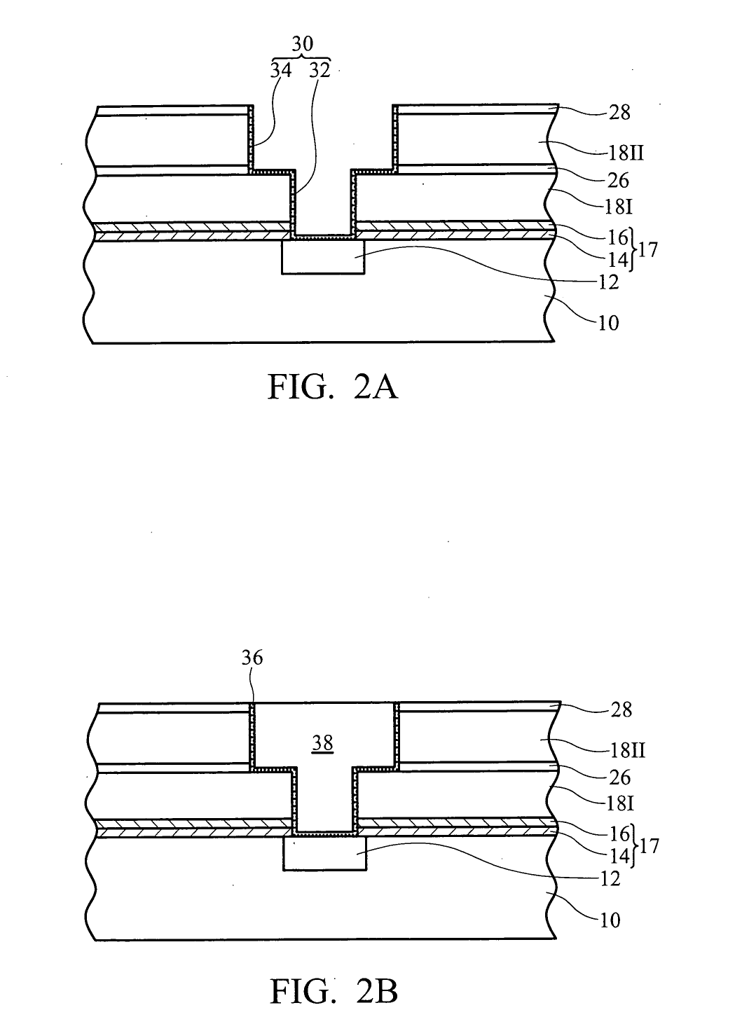

FIGS. 2A to 2B are cross-sectional diagrams illustrating a copper dual damascene process according to an embodiment of the present invention, wherein similar features or elements are denoted by similar reference numerals and explanation of the same or similar portions to the description in FIGS. 1A-1C will be omitted.

Referring to FIG. 2A, an example of a substrate 10 used for copper dual damascene fabrication is illustrated. Compared with the via hole 20 fabricated in the low-k dielectric layer 18 shown in FIG. 1B, FIG. 2A depicts the composite SiN/SiC structure 17 laminated thereupon a first low-k dielectric layer 18I, a middle etch stop layer 26, a second low-k dielectric layer 18II and a polish stop layer 28 successively, wherein a dual damascene opening 30 including an upper trench section 34 and a lower via hole section 32 is defined to expose the conductive region 12. In implementing dual damascene techniques, a middle etch stop layer 26 is deposited between the two low-k dielectric layers 18I and 18II. A photoresist mask (not shown) is then provided, and anisotropic etching is conducted to form a via hole through the polish stop layer 28, the second low-k dielectric layer 18II, the middle etch stop layer 26, the first low-k dielectric layer 18I and the composite SiN/SiC structure 17. Subsequently, the photoresist mask for the via hole is removed, and then a photoresist mask (not shown) for a trench is provided and anisotropic etching is conducted to form a trench through the polish stop layer 28, the second low-k dielectric layer 18II and the middle etch stop layer 26. It is understood that those skilled in the art and having reference to this specification will readily comprehend the manner in which the locations of the upper trench section 34 and the lower via section 32 may be defined in this dual damascene manner.

The middle etch stop layer 26 is chosen for its high selectivity with respect to the overlying second low-k dielectric layer 18II, and also functions as an anti-reflective coating (ARC). Suitable materials for the middle etch stop layer 26 having a thickness of about 200 angstroms to about 800 angstroms may include, but not limited to, silicon nitride, silicon oxynitride, silicon carbide, combinations thereof, or the like using CVD, PECVD, PVD, and future-developed deposition procedures. In an embodiment of the present invention, the middle etch stop layer 26 may be optionally omitted between the two low-k dielectric layers 18I and 18II.

The polish stop layer 28 may be optionally implemented, which has a very negligible polish rate in the CMP process used to polish the metal features during the damascene process. The polish stop layer 28 may under certain circumstances be formed employing methods, materials and thickness dimensions analogous or equivalent to the methods, materials and thickness dimensions as employed for forming the SiN layer 14, the SiC layer 16, the middle etch stop layer 26, or combinations thereof. Typically and preferably, the polish stop layer 28 is formed to a thickness of about 100 angstroms to about 1000 angstroms.

Referring to FIG. 2B, a diffusion barrier layer 36 is deposited on the substrate 10 to conformally cover the bottom and the sidewalls of the dual damascene opening 30 and extend on to the polish stop layer 28. A conductive layer 38 is then formed on the diffusion layer 36 to fill the dual damascene opening 30. Next, portions of the conductive layer 38 and the diffusion barrier layer 36 extended on to the polish stop layer 28 are removed and planarized by means of CMP or other suitable etch back processes. At this time, it is preferred that the CMP process levels off the conductive layer 38 and the polish stop layer 28. The conductive layer 38 may under certain circumstances be formed employing methods, materials and thickness dimensions analogous or equivalent to the methods, materials and thickness dimensions as employed for forming the conductive layer 22 described in FIGS. 1C and 1D. Typically and preferably, the conductive layer 38 may include copper or copper-based alloy. The diffusion barrier layer 36 may under certain circumstances be formed employing methods, materials and thickness dimensions analogous or equivalent to the methods, materials and thickness dimensions as employed for forming the diffusion barrier layer 24 described in FIG. 1D. Typically and preferably, the diffusion barrier layer 36 may include a refractory material or other materials that can inhibit diffusion of copper into the low-k dielectric layers 18I and 18II.

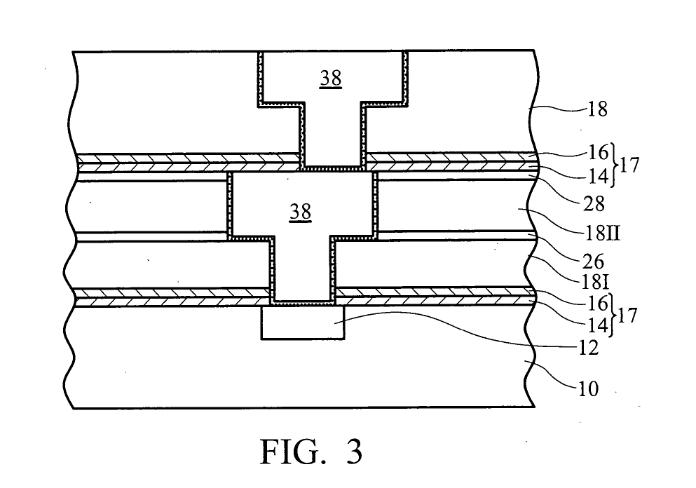

FIG. 3 is a cross-sectional diagram illustrating an exemplary implantation of a copper dual damascene pattern according to the present invention, wherein similar features or elements are denoted by similar reference numerals and explanation of the same or similar portions to the description in FIGS. 2A-2B will be omitted. After planarizing the conductive layer 38, the above-described dual damascene steps are repeated to form subsequent copper damascene structures.

Embodiments of the present invention, therefore, enable the fabrication of semiconductor device having copper interconnection patterns with feature sizes in the deep sub-micron regime with not only high circuit speed employing various low-k materials, but also with extremely high reliability. The present invention is particularly applicable to interconnect technology involving damascene techniques.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. An interconnect structure, comprising:
a substrate comprising a conductive region;
a silicon nitride layer overlying said substrate;
a silicon carbide layer overlying said silicon nitride layer;
at least one dielectric layer having a dielectric constant less than 3.9 overlying said silicon carbide layer; and
a conductive layer inlaid said at least one dielectric layer, said silicon carbide layer and said silicon nitride layer, wherein said conductive layer is electrically connected to said conductive region.

2. The interconnection structure of claim 1, wherein said conductive layer is formed in a via hole which penetrates said at least one dielectric layer, said silicon carbide layer and said silicon nitride layer to expose said conductive region.

3. The interconnection structure of claim 1, wherein said conductive layer is formed in a dual damascene opening which penetrates said at least one dielectric layer, said silicon carbide layer and said silicon nitride layer to expose said conductive region.

4. The interconnection structure of claim 1, wherein said silicon nitride layer has a thickness of about 10 angstroms to 1000 angstroms.

5. The interconnection structure of claim 1, wherein said silicon carbide layer has a thickness of about 10 angstroms to 1000 angstroms.

6. The interconnection structure of claim 1, wherein said conductive layer comprises copper or copper alloy.

7. The interconnection structure of claim 1, wherein said at least one dielectric layer has a dielectric constant less than 3.5.

8. The interconnection structure of claim 1, wherein said conductive region comprises copper or copper alloy.

9. The interconnection structure of claim 1, further comprising a diffusion barrier layer surrounding the sidewalls and bottom of said conductive layer.

10. The interconnection structure of claim 9, wherein said diffusion barrier layer comprises a refractory material, TiN, TaN, Ta, Ti, W, WN, Cr, Nb, or combinations thereof.

11. An interconnect structure, comprising:
a substrate comprising a conductive region;
a silicon nitride layer overlying said substrate;
a silicon carbide layer overlying said silicon nitride layer;
a first dielectric layer having a dielectric constant less than 3.9 overlying said silicon carbide layer;
a second dielectric layer having a dielectric constant less than 3.9 overlying said first dielectric layer; and
a conductive layer within a dual damascene opening formed in said second dielectric layer, said first dielectric layer, said silicon carbide layer and said silicon nitride layer, wherein said conductive layer is electrically connected to said conductive region.

12. The interconnect structure of claim 11, wherein said dual damascene opening comprises:
a trench section adjacent to said second dielectric layer; and
a via hole section adjacent to said first dielectric layer, said silicon carbide layer and said silicon nitride layer.

13. The interconnection structure of claim 11, further comprising an etch stop layer sandwiched between said first dielectric layer and said second dielectric layer.

14. The interconnection structure of claim 11, further comprising a polish stop layer overlying said second dielectric layer.

15. The interconnection structure of claim 11, further comprising a diffusion barrier layer surrounding the sidewalls and bottom of said conductive layer.

16. The interconnection structure of claim 15, wherein said diffusion barrier layer comprises a refractory material, TiN, TaN, Ta, Ti, W, WN, Cr, Nb, or combinations thereof.

17. The interconnection structure of claim 11, wherein said silicon nitride layer has a thickness of about 10 angstroms to 1000 angstroms.

18. The interconnection structure of claim 11, wherein said silicon carbide layer has a thickness of about 10 angstroms to 1000 angstroms.

19. The interconnection structure of claim 11, wherein said conductive layer comprises copper or copper alloy.

20. The interconnection structure of claim 11, wherein at least one of said first dielectric layer and said second dielectric layer has a dielectric constant less than 3.5.

21. The interconnection structure of claim 11, wherein said conductive region comprises copper or copper alloy.

22. A method of forming an interconnect structure, comprising the steps of:
providing a substrate having a conductive region;
forming a silicon nitride layer overlying said substrate;
forming a silicon carbide layer overlying said silicon nitride layer;
forming at least one dielectric layer having a dielectric constant less than 3.9 overlying said silicon carbide layer;
forming an opening in said at least one dielectric layer, said silicon carbide layer and said silicon nitride layer to expose said conductive region; and
filling said opening with a conductive layer.

23. The method of claim 22, wherein said silicon nitride layer and said silicon carbide layer are formed employing ex-situ depositions or in-situ depositions.

24. The method of claim 22, wherein the step of forming said at least one dielectric layer comprises:
forming a first dielectric layer having a dielectric constant less than 3.9 overlying said silicon carbide layer; and
forming a second dielectric layer having a dielectric constant less than 3.9 overlying said first dielectric layer.

25. The method of claim 24, wherein the step of forming said opening comprises:
forming a trench section adjacent to said second dielectric layer; and
forming a via hole section adjacent to said first dielectric layer, said silicon carbide layer and said silicon nitride layer.

26. The method of claim 24, further comprising the step of: forming an etch stop layer between said first dielectric layer and said second dielectric layer.

27. The method of claim 24, further comprising the step of: forming a polish stop layer overlying said second dielectric layer before the step of forming said opening.

28. The method of claim 22, further comprising the step of: forming a diffusion barrier layer along the sidewalls and bottom of said opening before the step of filling said opening with said conductive layer.

29. The interconnection structure of claim 28, wherein said diffusion barrier layer comprises a refractory material, TiN, TaN, Ta, Ti, W, WN, Cr, Nb, or combinations thereof.

30. The method of claim 22, further comprising the step of: performing a chemical mechanical polishing process on said conductive layer.

31. The method of claim 22, further comprising the step of: performing a chemical mechanical polishing process on said conductive region before the step of forming said silicon nitride layer.

32. The method of claim 22, wherein said silicon nitride layer has a thickness of about 10 angstroms to 1000 angstroms.

33. The interconnection structure of claim 22, wherein said silicon carbide layer has a thickness of about 10 angstroms to 1000 angstroms.

34. The interconnection structure of claim 22, wherein said conductive layer comprises copper or copper alloy.

35. The interconnection structure of claim 22, wherein said conductive region comprises copper or copper alloy.
